(19) United States
(12) Patent Application Publication
(10) Pub. No.: US 2025/0239583 A1
(43) Pub. Date: Jul. 24, 2025

(54) FILM FORMATION APPARATUS AND METHOD OF TRANSPORTING SUBSTRATE

(71) Applicant: ULVAC, Inc., Chigasaki-shi (JP)

(72) Inventors: Takuya FUJII, Chigasaki-shi (JP); Takahito KIMOTO, Chigasaki-shi (JP); Junichi SAKAMOTO, Chigasaki-shi (JP)

(21) Appl. No.: 19/032,717

(22) Filed: Jan. 21, 2025

(30) Foreign Application Priority Data
Jan. 23, 2024 (JP) 2024-008195

(51) Int. Cl. H01M 4/04; H01M 4/02; H01M 4/40

(52) U.S. Cl. CPC H01M 4/0409; H01M 4/0435; H01M 4/405; H01M 2004/027

(57) ABSTRACT

The invention relates to a film formation apparatus and a transportation method. The film formation apparatus includes a transport unit configured to transport a substrate, and a film formation unit configured to deposit a Li metal in a vacuum onto a film formation region of the substrate transported by the transport unit. The transport unit includes a plurality of rollers. At least one of the plurality of rollers is a wrinkle prevention roller. A static friction coefficient between the wrinkle prevention roller and the Li metal measured under an atmosphere with a dew point of −40° C. or lower is greater than 0.50 and equal to or less than 2.50. A Young's modulus of a surface of the wrinkle prevention roller is 2.5 GPa or less. The surface of the wrinkle prevention roller is formed of polypropylene.

### CROSS-REFERENCE TO RELATED APPLICATION

The present application claims a priority based on Japanese Patent Application No. 2024-008195 filed on Jan. 23, 2024 and the content thereof is incorporated by reference herein.

### BACKGROUND OF THE INVENTION

### Field of the Invention

The present invention relates to a film formation apparatus and a method of transporting a substrate.

### Description of Related Art

Lithium batteries have attracted attention as batteries installed in mobile devices such as smartphones. In a manufacturing process of lithium batteries, there is a problem in that wrinkles occur during transportation after Li metal is deposited onto a flexible substrate. Particularly, occurrence of wrinkles along a transport path from after deposition onto the flexible substrate to winding of the flexible substrate is a problem. Cylindrical rollers are used in transport of the flexible substrate such as, for example, a web-shaped substrate. During transportation of the flexible substrate, if a compressive stress generated in the flexible substrate, on the roller, exceeds a critical buckling stress of the flexible substrate, wrinkles occur. The phenomenon of wrinkle formation has been modeled. Parameters constituting this model include, for example, a Young's modulus in a transport direction and a width direction of the flexible substrate, a Poisson's ratio of the flexible substrate, a thickness of the flexible substrate, a width of the flexible substrate, a tension, and a static friction coefficient. It is said that, when these parameters are substituted into the model, occurrence of wrinkles can be theoretically predicted.

The parameters of such a model are not limited to equipment control parameters. Particularly, among the parameters of the above-described model, a tension related to physical property values of the flexible substrate, which is an object to be produced, is also a parameter that depends on types of flexible substrate and a surface processing process such as physical vapor deposition (PVD). Therefore, it is preferable to adjust a friction coefficient as a parameter of the model.

As a transport technology for adjusting the friction coefficient, Japanese Unexamined Patent Application, First Publication No. H7-257798 (hereinafter, referred to as Patent Literature 1) discloses a guide roller that winds and transports a thin object such as paper. In this guide roller, low friction coefficient members with a low friction coefficient with paper and high friction coefficient members with a high friction coefficient with paper are alternately disposed parallel to a guide roller axis on an outer circumferential surface at which the guide roller comes into contact with the transported object.

As a transport technology for adjusting the friction coefficient, Japanese Unexamined Patent Application, First Publication No. 2023-78132 (hereinafter, referred to as Patent Literature 2) discloses a roller device (100) for guiding a flexible substrate (10). In this roller device (100), the roller device includes a support surface (110) for being brought into contact with the flexible substrate (10). The support surface (110) has a coating (120) that contains an electronegative polymer.

However, even with the use of the technologies in Patent Literature 1 and 2, it was not possible to sufficiently suppress occurrence of wrinkles when a flexible substrate having a Li metal surface was transported under vacuum conditions.

The invention has been made in consideration of the above-described circumstances, and an objective of the invention is to provide a film formation apparatus and a method of transporting a substrate which can suppress occurrence of wrinkles even when a substrate having a Li metal surface is transported under vacuum conditions.

### SUMMARY OF THE INVENTION

A film formation apparatus according to a first aspect of the invention includes a transport unit configured to transport a substrate, and a film formation unit configured to deposit a Li metal in a vacuum onto a film formation region of the substrate transported by the transport unit. The transport unit includes a plurality of rollers. At least one of the plurality of rollers is a wrinkle prevention roller. A static friction coefficient between the wrinkle prevention roller and the Li metal measured under an atmosphere with a dew point of −40° C. or lower is greater than 0.50 and equal to or less than 2.50. A Young's modulus of a surface of the wrinkle prevention roller is 2.5 GPa or less. The surface of the wrinkle prevention roller is formed of polypropylene. Therefore, the above-described problem has been solved.

In the film formation apparatus according to a second aspect of the invention, the film formation apparatus according to the first aspect may be configured so that a dynamic friction coefficient between the wrinkle prevention roller and the Li metal measured under an atmosphere with a dew point of −40° C. or lower is in a range of 0.10 to 1.20.

In the film formation apparatus according to a third aspect of the invention, the film formation apparatus according to the first aspect or the second aspect may be configured so that a surface free energy of the surface of the wrinkle prevention roller is 40 mN/m or less.

A transportation method according to a fourth aspect of the invention transports the substrate using the wrinkle prevention roller of the film formation apparatus according to the first aspect or the second aspect.

The film formation apparatus according to the first aspect of the invention includes a transport unit configured to transport a substrate, and a film formation unit configured to deposit a Li metal in a vacuum onto a film formation region of the substrate transported by the transport unit. The transport unit includes a plurality of rollers. At least one of the plurality of rollers is a wrinkle prevention roller. A static friction coefficient between the wrinkle prevention roller and the Li metal measured under an atmosphere with a dew point of −40° C. or lower is greater than 0.50 and equal to or less than 2.50. A Young's modulus of a surface of the wrinkle prevention roller is 2.5 GPa or less. The surface of the wrinkle prevention roller is formed of polypropylene.

Therefore, since at least one of the plurality of rollers is a wrinkle prevention roller, elastic recovery due to a bending rigidity of the substrate can be promoted. Specifically, a stress exerted on the substrate in contact with the surface of the roller can be kept within an elastic deformation range. Also, since the Young's modulus of a surface of the wrinkle prevention roller is 2.5 GPa or less, deformation of the substrate in contact with the surface of the roller can be suppressed to an appropriate range. Therefore, in the film formation apparatus according to the first aspect of the invention, after the Li metal is deposited in a vacuum, the substrate having a Li metal layer on a surface thereof can be transported while occurrence of wrinkles is suppressed.

In the film formation apparatus according to the second aspect of the invention, the film formation apparatus according to the first aspect is configured so that a dynamic friction coefficient between the wrinkle prevention roller and the Li metal measured under an atmosphere with a dew point of −40° C. or lower is in a range of 0.10 to 1.20. Therefore, elastic recovery due to a bending rigidity of the substrate can be further promoted.

In the film formation apparatus according to the third aspect of the invention, the film formation apparatus according to the first aspect or the second aspect is configured so that a surface free energy of the surface of the wrinkle prevention roller is 40 mN/m or less.

Therefore, it can be made easier to reduce the static friction coefficient between the roller and the Li metal to 2.50 or less.

Therefore, elastic recovery due to a bending rigidity of the substrate can be further promoted. Further, deformation of the substrate in contact with the surface of the roller can be suppressed to a more appropriate range. Also, a reaction between the surface of the wrinkle prevention roller and Li can be suppressed, and therefore a lifespan of the roller can be prolonged.

In the transportation method according to the fourth aspect of the invention, the substrate is transported using the wrinkle prevention roller of the film formation apparatus according to the first aspect or the second aspect.

Therefore, even when the substrate having a Li metal layer on a surface thereof is transported under vacuum conditions, occurrence of wrinkles can be suppressed. According to the above-described aspects of the invention, even when a substrate having a Li metal layer on a surface thereof is transported under vacuum conditions, occurrence of wrinkles can be suppressed.

### BRIEF DESCRIPTION OF THE DRAWINGS

FIG. 1 is a schematic view showing an example of a film formation apparatus according to one embodiment of the invention.

FIG. 2 is a cross-sectional view showing a base member having a Li metal layer.

FIG. 3 is an explanatory view showing an example of a wrinkle prevention roller shown in FIG. 1.

### DETAILED DESCRIPTION OF THE INVENTION

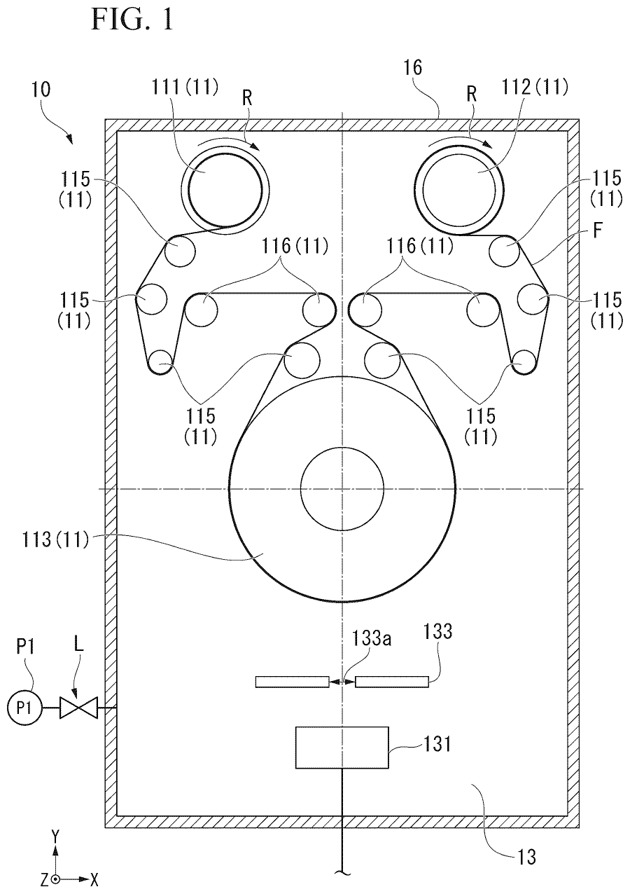

Hereinafter, a roller, a film formation apparatus, and a transportation method according to an embodiment of the invention will be described. FIG. 1 is a schematic view showing a film formation apparatus according to the present embodiment. In FIG. 1, reference numeral 10 denotes a film formation apparatus. As a film formation apparatus, for example, a deposition apparatus may be adopted. In FIG. 1, X-axis, Y-axis, and Z-axis directions indicate three axial directions that are orthogonal to each other. The X-axis and Y-axis indicate a horizontal direction. The Z-axis direction is a direction orthogonal to the horizontal direction. That is, the Z-axis direction indicates a vertical direction.

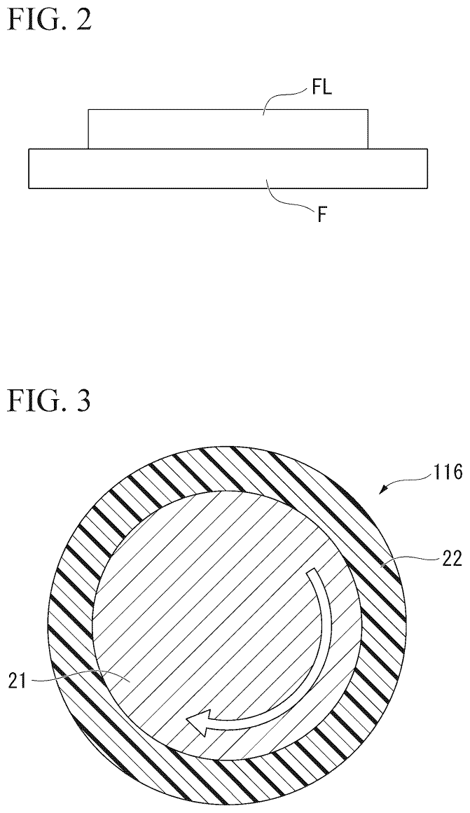

The film formation apparatus 10 according to the present embodiment is configured to form a Li metal layer FL containing Li metal on a base member F (substrate) as shown in FIG. 2. In the film formation apparatus 10, the Li metal layer FL may be formed on only one side of the base member F, or on both sides of the base member F.

As shown in FIG. 1, the film formation apparatus 10 according to the present embodiment includes a vacuum chamber 16 (chamber), a transport unit 11, and a film formation unit 13.

In the present embodiment, a case in which the film formation apparatus 10 is a roll-to-roll apparatus will be described. The invention is not limited to a configuration of the roll-to-roll apparatus. For example, it is possible to have a configuration in which a sheet substrate is transported using rollers while a film is formed on the transported sheet substrate.

(Vacuum chamber 16)

The vacuum chamber 16 in the film formation apparatus 10 has a sealable structure. The vacuum chamber 16 is connected to an exhaust line L having a vacuum pump P1. The vacuum chamber 16 is configured so that the inside can be evacuated to or maintained at a predetermined reduced pressure atmosphere.

(Transport unit 11)

The transport unit 11 is configured to transport the base member F within the vacuum chamber. In the present embodiment, the transport unit 11 has an unwinding roller 111, a winding roller 112, a main roller 113, and a plurality of rollers 115 and 116. The roller 116 that comes into contact with the deposited Li metal layer FL is an example of a wrinkle prevention roller to be described later.

Each of the unwinding roller 111 and the winding roller 112 includes a rotation driver (not shown in the drawings). Each of the unwinding roller 111 and the winding roller 112 is configured to be rotatable in a direction of arrow R at a predetermined rotation speed around an axis extending in the Z-axis direction orthogonal to the plane of the paper in FIG. 1.

The main roller 113 includes a rotation driver (not shown in the drawings). The main roller 113 is configured to be rotatable in a direction opposite to the direction of arrow R at a predetermined rotation speed around an axis extending in the Z-axis direction orthogonal to the plane of the paper in FIG. 1.

The unwinding roller 111 is provided upstream of the film formation unit 13 in a transport direction of the base member F. The unwinding roller 111 has a function of feeding the base member F toward the main roller 113. Further, an appropriate number of guide rollers (not shown in the drawings) that do not have a rotation driver may be disposed at appropriate positions between the unwinding roller 111 and the main roller 113.

The main roller 113 is configured to be rotatable around an axis extending in the Z-axis direction orthogonal to the plane of the paper in FIG. 1. The main roller 113 is disposed between the unwinding roller 111 and the winding roller 112 in the transport direction of the base member F. At least a part of a lower portion of the main roller 113 in the Y-axis direction in FIG. 1 faces a deposition source 131 to be described later. In other words, at least a part of the lower portion of the main roller 113 is disposed at a position facing the deposition source 131 to be described later through an opening 133a provided in a shield 133 (shielding portion) to be described later.

The main roller 113 faces the opening 133a with a predetermined distance therebetween. The main roller 113 faces the deposition source 131 in the Y-axis direction. The main roller 113 is formed in a cylindrical shape from a metal material such as stainless steel, iron, or aluminum. Inside the main roller 113, a temperature control mechanism such as, for example, a temperature control medium circulation system (not shown in the drawings) may be provided. A size of the main roller 113 is not particularly limited, but typically, a width of the main roller 113 in the Z-axis direction is set to be larger than a width of the base member F in the Z-axis direction. Each of the rollers 115 and 116 is configured to be rotatable around an axis extending in the Z-axis direction orthogonal to the plane of the paper in FIG. 1. Each of the plurality of rollers 115 and 116 may or may not be driven. The roller 116 that comes into contact with the Li metal layer FL is the wrinkle prevention roller to be described later. Therefore, even when the base member F is transported, occurrence of wrinkles is suppressed by the wrinkle prevention roller.

Therefore, in the vacuum chamber, the base member F can be transported from the unwinding roller 111 toward the winding roller 112 at a predetermined transport speed while suppressing wrinkles.

### (Wrinkle Prevention Roller)

The roller 116 functioning as a wrinkle prevention roller is a roller transporting the base member F having the Li metal layer FL. A static friction coefficient between the roller 116 and the Li metal is greater than 0.50 and equal to or less than 2.50. A surface of the roller 116 has a Young's modulus of 2.5 GPa or less. FIG. 3 shows an example of the roller 116. As shown in FIG. 3, the roller 116 has a cylindrical rotating member 21 and a support surface layer 22. The support surface layer 22 covers at least a region of an outer circumferential surface of the rotating member 21 that comes into contact with the Li metal. A surface of the wrinkle prevention roller is formed of polypropylene. The arrow shown in FIG. 3 indicates a rotation direction of the roller 116.

(Rotating member 21)

The rotating member 21 is formed in a cylindrical shape from a metal material such as, for example, stainless steel, iron, or aluminum.

(Support surface layer 22)

The support surface layer 22 covers at least a region of an outer circumferential surface of the rotating member 21 that comes into contact with the Li metal. The support surface layer 22 may cover the entire outer circumferential surface of the rotating member 21. A thickness of the support surface layer 22 is not particularly limited as long as it can transport the base member F. The thickness of the support surface layer 22 is, for example, in a range of 1 mm to 100 mm.

### (Static Friction Coefficient)

A static friction coefficient between the roller 116 and the Li metal (hereinafter, may be referred to as a static friction coefficient with respect to Li) is greater than 0.50 and equal to or less than 2.50. Here, a static friction coefficient between the support surface layer 22 and the Li metal is the static friction coefficient with respect to Li. When the static friction coefficient between the roller 116 and the Li metal is set to be greater than 0.50 and equal to or less than 2.50, elastic recovery due to a bending rigidity of the substrate can be promoted.

### (Dynamic Friction Coefficient)

A dynamic friction coefficient between the roller 116 and the Li metal (hereinafter, may be referred to as a dynamic friction coefficient with respect to Li) is preferably in a range of 0.10 to 1.20. Here, a dynamic friction coefficient between the support surface layer 22 of the roller and the Li metal is the dynamic friction coefficient with respect to Li. When the dynamic friction coefficient between the roller 116 and the Li metal is set to in a range of 0.10 to 1.20, the elastic recovery due to a bending rigidity of the substrate can be further promoted.

A ratio of the static friction coefficient with respect to Li to the dynamic friction coefficient with respect to Li (static friction coefficient with respect to Li/dynamic friction coefficient with respect to Li) is preferably in a range of 1.00 to 2.50. When the static friction coefficient with respect to Li/dynamic friction coefficient with respect to Li is set in a range of 1.00 to 2.50, the elastic recovery due to a bending rigidity of the substrate can be further promoted, and occurrence of wrinkles can be further suppressed.

The static friction coefficient and the dynamic friction coefficient of the roller 116 can be measured, for example, by the following method. In this measurement, an automatic friction and wear analyzer (for example, TSf-303 manufactured by Kyowa Interface Science Co., Ltd., hereinafter may be referred to as an analyzer) is used. A sample of the same material as that of an outer circumferential surface of the roller 116 is disposed on a lower surface of the analyzer. A copper foil coated with the Li metal is attached to the contactor using a double-sided tape. A shape and specifications of the contactor are, for example, a surface contactor manufactured by Kyowa Interface Science Co., Ltd. (TSf No. 9210 with a contact surface size of 10 mm×10 mm). In a measurement conducted under an atmosphere with a dew point of −40° C. or lower, the measurement is performed three times under conditions of a distance of 50 mm, a speed of 100 mm/s, and a load of 100 g. Obtained average values of the static friction coefficient and the dynamic friction coefficient are defined as a static friction coefficient with respect to Li and a dynamic friction coefficient with respect to Li, respectively.

### (Young's Modulus)

A Young's modulus of the surface (outer circumferential surface) of the roller 116 is 2.5 GPa or less. Here, the Young's modulus of the surface is defined as a Young's modulus of the support surface layer 22. When the Young's modulus of the surface is set to 2.5 GPa or less, deformation of the substrate in contact with the surface of the roller can be suppressed to an appropriate range. The Young's modulus may be 0.5 GPa or more.

The Young's modulus of the surface can be measured by the following method. A sample of the same material as that of the surface of the roller 116 is prepared. The sample can be measured in accordance with JIS K 7161.

### (Surface Free Energy)

It is preferable that a surface free energy of the outer circumferential surface of the roller 116 is 40 mN/m or less. When the surface free energy is 40 mN/m or less, the static friction coefficient with respect to Li is likely to become 2.50 or less. Further, when the surface free energy is set in this way, it is possible to prevent a change in each friction coefficient (each of the static friction coefficient and the dynamic friction coefficient), and to maintain a stable friction coefficient over a long period of time. The surface free energy is more preferably 30 mN/m or less. Therefore, at least one of preventing adhesion and suppressing corrosion wear can be expected. Therefore, it is possible to maintain even greater long-term stability. Here, the surface free energy of the roller 116 is defined as a surface free energy of the support surface layer 22.

The surface free energy of the roller 116 can be measured by the following method. The surface free energy can be measured using a general-purpose contact angle meter. Specifically, a liquid with a known surface free energy value (water, methylene iodide) is used. A contact angle of the sample is measured and a theoretical formula of D. K. Owens and R. C. Wendt, J. Appl. Polym. Sci., 13, 1741 (1969) is used. Therefore, the surface free energy of the sample can be calculated. For example, 2 μl of pure water and diiodomethane are each dropped onto a test piece taken from the surface of the roller 116, and a contact angle (θ) is measured using a contact angle meter. Using the obtained contact angle, a surface free energy value γₛ can be determined by a calculation according to the following Owens equation.

$$1 + cos θ = 2 [ {( {γ}_{s}^{d} {γ}_{1}^{d} )}^{1 / 2} / {γ}_{1} + {( {γ}_{s}^{p} {γ}_{1}^{p} )}^{1 / 2} / {γ}_{1} ]$$

Here, in the equation described above, γₛ represents a surface free energy of a solid, γ₁ represents a surface free energy of a liquid, the subscript d represents a dispersion force component, and the subscript p represents a polar force component.

(Arithmetic mean surface roughness Sa)

The arithmetic mean surface roughness Sa of the outer circumferential surface of the roller 116 is preferably 1.00 μm or less. When the arithmetic mean surface roughness Sa of the outer circumferential surface of the roller 116 is set to 1.00 μm or less, occurrence of wrinkles can be further suppressed.

The arithmetic mean surface roughness Sa can be determined in accordance with ISO 25178. A test piece may be taken from the surface of the roller 116 and measured.

The surface of the roller 116 is preferably formed of one or more selected from the group consisting of polypropylene, polyethylene, and polytetrafluoroethylene. When the support surface layer 22 is provided, it is preferable that the support surface layer 22 contains one or more selected from the group consisting of polypropylene, polyethylene, and polytetrafluoroethylene. When the surface of the roller 116 is formed of one or more selected from the group consisting of polypropylene, polyethylene, and polytetrafluoroethylene, the elastic recovery due to a bending rigidity of the base member F can be further promoted. Further, deformation of the substrate in contact with the surface of the roller can be suppressed to a more appropriate range. The surface of the roller 116 is more preferably formed of polypropylene. If the support surface layer 22 is provided, the support surface layer 22 is preferably formed of polypropylene. When the surface of the roller 116 is formed of polypropylene, a reaction between the surface of the roller 116 and the Li metal can be suppressed. Therefore, at least one of preventing adhesion and suppressing corrosion wear can be expected. Therefore, it is possible to maintain even greater long-term stability.

In the film formation apparatus 10, at least one of the plurality of rollers 115 and 116 is a wrinkle prevention roller. The static friction coefficient between the wrinkle prevention roller and the Li metal is 2.50 or less. The Young's modulus of the surface of the wrinkle prevention roller is 2.5 GPa or less.

When a roller of the plurality of rollers 115 and 116 that comes into contact with the Li metal layer FL is defined as a contact roller, it is preferable that a ratio of the number of wrinkle prevention rollers to a total number of the contact rollers is 30% or more. In this case, since the contact ratio between the Li metal layer FL and the wrinkle prevention roller increases, the base member F can be transported while occurrence of wrinkles is suppressed. Here, since the contact rollers may all be wrinkle prevention rollers, the ratio of the number of wrinkle prevention rollers to the total number of contact rollers may be 100%. In this way, occurrence of wrinkles can be further suppressed.

### (Film Formation Unit 13)

The film formation unit 13 deposits the Li metal layer FL onto a film formation region of the base member F in a vacuum. Since the Li metal is deposited in a vacuum, only an unavoidable reaction layer due to oxidation or the like is present on a surface of the Li metal layer FL. The film formation unit 13 includes the deposition source 131 and the shield 133 therein. Also, the film formation unit 13 is connected to an exhaust line (not shown in the drawings). The main roller 113 constitutes the film formation unit 13.

The deposition source 131 (film formation source supplier) of the film formation unit 13 is a Li deposition source that evaporates the Li metal. The deposition source 131 is constituted by, for example, a resistance heating type deposition source, an induction heating type deposition source, an electron beam heating type deposition source, or the like.

The film formation unit 13 is maintained at a predetermined reduced pressure atmosphere by the exhaust line L.

As shown in FIG. 1, the shield 133 is provided in the film formation unit 13 between the deposition source 131 (film formation source) and the main roller 113. The shield 133 has the opening 133a. The opening 133a is a film formation range defining portion that defines a film formation range.

The shield 133 is disposed to be substantially parallel to the base member F wound around the main roller 113.

The base member F is, for example, a long film cut to a predetermined width. In the example shown in FIG. 1, a width of the base member F is a length of the base member F in the Z-axis direction. The base member F is formed of a metal such as copper, nickel, stainless steel, or iron. A material of the base member F is not limited to such a material. As a material for the base member F, a resin film such as a polyethylene (PE) film, a non-oriented polypropylene (CPP) film, an oriented polypropylene (OPP) film, a polyethylene terephthalate (PET) film, a polyethylene naphthalate (PEN) film, a polyphenylene sulfite (PPS) film, or a polyimide (PI) film may be used. A thickness of the base member F is not particularly limited and is, for example, in a range of 1 μm to 20 μm. Also, the width or length of the base member F is not particularly limited, and can be determined as appropriate according to applications.

The Li metal layer FL present on the base member F is generally formed by deposition. The inventors have considered that, when a thickness of the Li metal layer FL is 0.1 μm or more, each friction coefficient, in which an influence of the Li metal layer becomes dominant, is exhibited. As for the reason, the inventors believe that, since Li metal has a relatively high surface tension, the Li metal layer takes an island-like or mesh structure when the thickness is less than 0.1 μm. As a result, since a part of the surface of the underlying base member F is exposed, the inventors believe that each friction coefficient exhibited with respect to the transporting roller is inevitably influenced by the underlying base member F, and therefore does not become the relevant friction coefficient. The inventors conducted experiments a plurality of times and ascertained that, under the above-described conditions, upper and lower limit values of dynamic friction coefficient samples fall within a range of 0.2 to 1.20.

In deposition onto a typical web-shaped continuous base member F (continuous substrate, substrate), it is difficult to form a film across 100% of the width of the continuous base member F due to technical constraints related to the apparatus and transportation and constraints related to the battery structure. Therefore, there are unavoidable non-deposited surfaces at both end potions of the continuous base member F in the width direction. That is, at both end potions of the continuous base member F in the width direction after the Li metal layer FL is deposited on the continuous base member F, there is a step formed by the deposited surface and the non-deposited surface.

This step is caused, for example, by the shield 133 that functions as a mask disposed during deposition. Here, the shield 133 functioning as a mask has a width smaller than that of the continuous base member F in the width direction. The shield 133 is disposed to prevent Li vapor evaporated from the deposition source 131 from reaching both end potions of the continuous base member F in the width direction.

Alternatively, this step can also be formed by a method of placing ribbon-shaped base members at both end potions of the continuous base member F, transporting the base members in synchronization with the continuous base member F, and thereby achieving a masking effect in a state in which the ribbon-shaped base members and the continuous base member F are in contact with each other.

Here, from the perspective of transporting the substrate without generating wrinkles on the base member, it is known that a location at which a normal force changes discontinuously at a contact portion between the base member and the transport roller can become a starting point for generating wrinkles when the change in the normal force exceeds a certain range. According to experiments conducted a plurality of times by the inventors, it has become apparent that, when the step is reduced to 20 μm or less, occurrence of wrinkles due to the transportation can be suppressed.

When the continuous base member is moved using transport rollers, preventing wrinkles can be achieved by making the normal force zero. However, when deposition is performed on the continuous base member F with a thickness of in a range of approximately 1 to 20 μm, it is necessary to apply the normal force due to tension or the like. The reason for this is that the normal force is applied to effectively facilitate heat removal through contact thermal conduction, thereby performing deposition without causing deformation, degradation, reactions, or the like of the base member due to heat. Also, the normal force acting on the Li metal layer in measuring each friction coefficient may physically disturb a surface layer of the Li metal layer containing an adsorbed gas. Therefore, it is preferable that the normal force be within a range of the tension used when the Li metal is deposited onto the continuous base member F. Generally, a tension across the width of the base member used when the Li metal is deposited onto the continuous base member is between 2.6 N/m and 260 N/m. Therefore, it is preferable to perform the measurement with the normal force in this range. Further, the static friction coefficients described above are measured by simulating the normal force corresponding to a tension of 50 N/m.

The tension across the width of the base member (applied tension/base member width) is preferably 260 N/m or less, and a product of the tension across the width of the base member and the static friction coefficient is preferably 650 N/m or less. When the product of the tension across the width of the base member and the static friction coefficient is 650 N/m or less, occurrence of wrinkles can be further suppressed.

The film formation apparatus 10 has the configuration as described above.

Further, although not shown in the drawings, the film formation apparatus 10 includes a control unit that controls the deposition source 131, the transport unit 11, the vacuum pump P1, and the like. The control unit is configured by a computer including a CPU and a memory, and controls an operation of the entire film formation apparatus 10.

Also, the configuration of the film formation apparatus 10 is not limited to that shown in the figure. The configuration of the film formation apparatus 10 such as, for example, a disposition, a size, or the like of the film formation unit 13, the transport unit 11, the vacuum pump, or the like, and the deposition source can be changed as appropriate. Alternatively, it is possible to omit any of the components in the above-described configuration of the film formation apparatus 10. Also, the film formation apparatus 10 may also have a configuration of depositing the Li metal layer FL using a sputtering method.

The arithmetic mean surface roughness Sa may be 0.02 μm or more.

The static friction coefficient with respect to Li/dynamic friction coefficient with respect to Li may be 1.15 or more. The static friction coefficient with respect to Li/dynamic friction coefficient with respect to Li may be 2.00 or less.

The dynamic friction coefficient with respect to Li may be greater than 0.50. When the dynamic friction coefficient with respect to Li exceeds 0.50, a transport efficiency of the base member F can be improved.

The film formation apparatus 10 may further include a first processing unit (not shown in the drawings) that oxidizes the surface of the Li metal layer FL. In the first processing unit, when the surface of the Li metal layer FL is oxidized, it is possible to stably secure predetermined electrical characteristics required for a negative electrode material of a lithium battery, and it facilitates stable formation of a lithium carbonate film to be described later.

In this case, the first processing unit includes a first processing chamber, a first gas supply line, and a first pressure control mechanism. In the first processing chamber, oxidation processing on the Li metal layer FL is performed using a first processing gas. The first gas supply line supplies the first processing gas to the first processing chamber. The first pressure control mechanism adjusts a pressure in the first processing chamber. The first processing gas is not particularly limited as long as it contains oxygen. The first processing gas is typically oxygen or a mixed gas of oxygen and argon. Due to the first pressure control mechanism, an atmosphere in the first processing chamber is maintained at a predetermined reduced pressure atmosphere, a gas pressure of the first processing gas in the first processing chamber is adjusted to a predetermined pressure, and the first processing gas is prevented from being discharged outside the first processing chamber.

The film formation apparatus 10 may further include a second processing unit (not shown in the drawings) that carbonates the surface of the oxidized Li metal layer FL. In the second processing unit, when the surface of the oxidized Li metal layer FL is carbonated, it becomes easier to effectively protect the surface of the Li metal layer FL from hydroxylation and nitridation.

In this case, the second processing unit includes a second processing chamber, a second gas supply line, and a second pressure control mechanism. In the second processing chamber, carbonation processing is performed on the Li metal layer FL using a second processing gas. The second gas supply line supplies the second processing gas to the second process chamber. The second pressure control mechanism adjusts a pressure in the second processing chamber. The second processing gas is not 5 particularly limited as long as it contains carbon and oxygen. Specifically, as the second processing gas, for example, a mixed gas of a rare gas such as argon and carbon dioxide is used. In this case, an amount of carbon dioxide contained in the second processing gas can also be set appropriately. For example, the amount of carbon dioxide in the second processing gas is approximately 5% by volume ratio. Due to the second pressure control mechanism, an atmosphere in the second processing chamber is maintained at a predetermined reduced pressure atmosphere, a gas pressure of the second processing gas in the second processing chamber is adjusted to a predetermined pressure, and the second processing gas is prevented from being discharged outside the second processing chamber. The second processing chamber may be configured as the same processing chamber as the first processing chamber. In this case, types of gas introduced into the first processing chamber are configured to be switchable.

The oxidation processing or the carbonation processing may be performed by introducing each of the first processing gas and the second processing gas into the vacuum chamber 16 without providing the first processing chamber and the second processing chamber.

When the Li metal layer FL is provided on both sides of the base member F, the main roller 113 may be used as a wrinkle prevention roller. Specifically, the main roller 113 may include the support surface layer 22.

In the present embodiment, the roller 116 is constituted by the cylindrical rotating member 21 and the support surface layer 22 that covers at least a region of the outer circumferential surface of the rotating member 21 that comes into contact with the Li metal. As a modified example, the roller 116 may be configured by a cylindrical rotating member formed of the same material as the support surface layer 22 described above.

### EXAMPLES

Hereinafter, examples of the invention will be described.

### (Wrinkle Prevention Roller)

A wrinkle prevention roller with a surface layer material of polypropylene (expressed as PP in Table 1) and a wrinkle prevention roller with a surface layer material of hard chrome-plated aluminum (expressed as HCr in Table 1) were prepared. For evaluations of a friction coefficient, a surface free energy, a Young's modulus, and a surface roughness, evaluation test pieces were used.

(Measurement of friction coefficient)

An automatic friction and wear analyzer (TSf-303 manufactured by Kyowa Interface Science Co., Ltd., hereinafter may be referred to as an analyzer) was used. A sample of the same material as that of an outer circumferential surface of the roller 116 is disposed on a lower surface of the analyzer. A copper foil coated with Li metal was attached to a contactor (a surface contactor manufactured by Kyowa Interface Science Co., Ltd. (TSf No. 9210 with a contact surface size of 10 mm×10 mm)). In a measurement conducted under an atmosphere with a dew point of −40° C. or lower, the measurement was performed three times under conditions of a distance of 50 mm, a speed of 100 mm/s, and a load of 100 g. Obtained average values of a static friction coefficient and a dynamic friction coefficient were defined as a static friction coefficient with respect to Li and a dynamic friction coefficient with respect to Li, respectively.

Measurement of each friction coefficient was conducted under a controlled atmospheric environment due to limitations of the analyzer. However, an atmosphere of the transport environment for preventing wrinkles, which is an object of the invention, is an atmosphere in which Li deposition is possible, and a surface of the Li metal layer immediately after deposition on the base member has a value in which an influence of an adsorbed gas molecule layer is excluded. Therefore, the inventors assume that the value will be approximately two to four times higher. The reason for this is that, in a pressure range on the order of 10-4 Pa or lower, in which Li deposition is generally performed, a nonlinear increase in the friction coefficient is expected as shown in FIG. 4 of Literature (Akira Kasahara, Ryusei Kim, Masahiro Tosa, Kazuhiro Yoshihara, “Measurement of Friction Force in High Vacuum Region,” J. Vac. Soc. Jpn., vol. 43, No. 10, p. 986-991 (2000), Non-Patent Literature 1). That is, from the perspective of preventing wrinkles, the measured values in an atmospheric environment, including measurement errors, should be considered as values multiplied by the above-described magnification factor, and careful handling is required.

### (Surface Free Energy)

2 μl of pure water and diiodomethane were each dropped onto a test piece (evaluation test piece) with the same surface material as the roller described above. Then, a contact angle (θ) was measured using a contact angle meter. Using the obtained contact angle, the surface free energy value γₛ was determined by a calculation according to the above-described Owens equation. A case in which the surface free energy of 40 mN/m or less was rated as A. A case in which the surface free energy greater than 40 mN/m and less than 60 mN/m was rated as B. A case in which the surface free energy of 60 mN/m or more was rated as C. Obtained results are shown in Table 1.

### (Young's Modulus)

The Young's modulus was measured for a test piece (evaluation test piece) with the same surface material as the above-described roller. The Young's modulus of PP was measured based on JIS K 7161. The Young's modulus of HCr—Al was measured based on JIS Z 2241. Obtained results are shown in Table 1.

### (Surface Roughness)

Using a sample (evaluation test piece) having the same surface material and surface roughness as the above-described roller, measurements were conducted in accordance with ISO25178. Obtained results are shown in Table 1.

The film formation apparatus shown in FIG. 1 having the wrinkle prevention roller shown in Table 1 was used. The Li metal layer was formed under the following transport speed and film formation conditions, and the transportation was carried out by the wrinkle prevention roller. A result in which no wrinkles occurred during transportation was rated as evaluation A. A result in which one or two wrinkles occurred due to transportation was rated as evaluation B. A result in which three or more wrinkles occurred due to transportation was rated as evaluation C. Obtained results are shown in Table 2.

Transport speed of base member F: a range of 0.01 to 20.0 m/min

Base member F: Cu foil (10 μm)

Thickness of Li metal formed in the film formation unit 13:5 μm

As shown in Table 2, in examples 1 and 2 which satisfied the conditions for the static friction coefficient and the Young's modulus, the number of occurred wrinkles was small.

In the present embodiment, the surface free energy of the support surface layer 22 was set to 40 mN/m or less. However, in a case in which deterioration of the resin caused by a high activation energy or the like of the Li metal layer immediately after deposition becomes a problem, it is more preferable that the surface free energy be 30 mN/m or less. In this way, it is possible to prevent a change in each friction coefficient due to deterioration of the resin, and maintain a stable friction coefficient over a long period of time.

Also, it is conceivable that a time-dependent change in each friction coefficient due to an oxidation-reduction reaction between Li and the resin, which is believed to be caused by contact with Li, may lead to occurrence of wrinkles. In this case, it is preferable to employ a configuration in which the surface layer of the support surface layer 22 does not contain fluorine. Therefore, it is possible to maintain a stable friction coefficient for a long period of time similarly to the above.

### (Tension)

In a case in which the rolls rated as evaluations A and B were used, a tension across a width of the base member used when Li metal was deposited onto the continuous base member was examined. As a result, it was found that occurrence of wrinkles could be further suppressed when the tension across the width of the base member (applied tension/base member width) was set to 260 N/m or less and a product of the tension across the width of the base member and the static friction coefficient was set to 650 N/m or less. Particularly, it was found that, when the product of the tension across the width of the base member and the static friction coefficient was 650 N/m or less, the occurrence of wrinkles can be further suppressed.

TABLE 1

| | | | | | | | Arithmetic |
|---|---|---|---|---|---|---|---|
| | | vs Li | vs Li | | | Surface | mean |
| | | (static | (dynamic | Ratio of | Young's | free | surface |
| Roll | Surface | friction | friction | friction | modulus | energy | roughness |
| No. | material | coefficient) | coefficient) | coefficient | (GPa) | (mN/m) | Sa (μm) |
| 1 | PP | 2.5 | 1.2 | 2.08 | 2.5 | A | 0.9 |
| 2 | HCr | 12.4 | 1.2 | 10.33 | 300 | C | 1.1 |

TABLE 2

| | | Ratio of number | |
|---|---|---|---|
| | | of wrinkle prevention | Evaluation |
| Experiment | Roll | rollers to number of | for |
| No. | No. | contact rollers (%) | wrinkle |
| 1 | 1 | 30 | B |
| 2 | 1 | 100 | A |
| 3 | 2 | 100 | C |

An example of application of the invention is an apparatus that performs alkali metal deposition.

While preferred embodiments of the invention have been described and shown above, it should be understood that these are exemplary of the invention and are not to be considered as limiting. Additions, omissions, substitutions, and other modifications can be made without departing from the spirit or scope of the invention. Accordingly, the invention is not to be considered as being limited by the foregoing description, and is only limited by the scope of the appended claims.

What is claimed is:

1. A film formation apparatus comprising:
a transport unit configured to transport a substrate having a film formation region; and
a film formation unit configured to deposit a Li metal in a vacuum onto the film formation region of the substrate transported by the transport unit, wherein
the transport unit includes a plurality of rollers,
at least one of the plurality of rollers is a wrinkle prevention roller,
a static friction coefficient between the wrinkle prevention roller and the Li metal measured under an atmosphere with a dew point of −40° C. or lower is greater than 0.50 and equal to or less than 2.50,
a Young's modulus of a surface of the wrinkle prevention roller is 2.5 GPa or less, and
the surface of the wrinkle prevention roller is formed of polypropylene.

2. The film formation apparatus according to claim 1, wherein
a dynamic friction coefficient between the wrinkle prevention roller and the Li metal measured under an atmosphere with a dew point of −40° C. or lower is in a range of 0.10 to 1.20.

3. The film formation apparatus according to claim 1, wherein
a surface free energy of the surface of the wrinkle prevention roller is 40 mN/m or less.

4. A method of transporting a substrate using a wrinkle prevention roller of the film formation apparatus according to claim 1.
